(19) United States
(12) Patent Application Publication
(10) Pub. No.: US 2009/0159001 A1
(43) Pub. Date: Jun. 25, 2009

(54) Shower head of chemical vapor deposition apparatus

(76) Inventor: Pyung-yong Um, Kyungki-do (KR)

Correspondence Address: HAYES SOLOWAY P.C., 3450 E. SUNRISE DRIVE, SUITE 140, TUCSON, AZ, 85718, US

(21) Appl. No.: 11/573,439

(22) PCT Filed: Aug. 9, 2005
(86) PCT No.: PCT/KR05/02581

§ 371 Date: Sep. 30, 2008

(30) Foreign Application Priority Data
Aug. 11, 2004 (KR) 10-2004-0063047

(51) Int. Cl. C23C 16/54

(52) U.S. Cl. 118/715

(57) ABSTRACT

There is provided a shower head capable of spraying a process reaction gas onto the surface of a semiconductor wafer to deposit the process reaction gas on the surface of the semiconductor wafer as a thin film of uniform thickness.

### TECHNICAL FIELD

The present invention relates to a shower head of a chemical vapor deposition apparatus capable of spraying a process reaction gas (hereinafter, referred to as a reaction gas) on the surface of a semiconductor wafer so that the reaction gas can be deposited on the surface of the semiconductor wafer as a thin film of uniform thickness.

### BACKGROUND ART

As illustrated in FIG. 1 that is a sectional view of a conventional chemical vapor deposition apparatus 1, the chemical vapor deposition apparatus 1 includes a chamber 10 having a chamber inside 11 so that a shower head 40 and a heater 50 are mounted therein, a gas in port 21 formed on one side so that a reaction gas is flown from the outside, a chamber lead 20 combined with the top surface of the chamber 10 by fastening means to seal up the chamber 10, a block plate 30 in which the received reaction gas is distributed by through holes 31 provided on the bottom surface of the chamber lead 20 to form a low temperature region, a plurality of spray holes 41 for spraying the distributed reaction gas onto the surface of a wafer 60, a shower head 40 having a plurality of fastening holes 42 formed along the outer circumference thereof to be fastened with the chamber lead 20, and a heater 50 on whose top surface the wafer 60 is settled and on whose bottom surface a heater supporter 51 is provided, the heater 50 being provided in the chamber inside 11 to be separated from the shower head 40 by a predetermined distance.

Thin film deposition using the chemical vapor deposition apparatus 1 is applied to a field of processing a material film on the surface of a wafer in fabrication of a semi-conductor device and an LCD substrate, to be specific, to fabrication of a wiring line apparatus having electric conductivity, deposition of an oxide film or a nitride film for insulating conductive material films using chemical, and deposition of a high dielectric thin film used for a DRAM or a flash memory device. The thin film is deposited in order to form an insulating film or a wiring line film having electrical characteristic in a CVD process of depositing a process reaction gas on the surface of a wafer in order to fabricate the semiconductor device or the LCD substrate.

As described above, the reaction gas is uniformly sprayed onto the surface of the wafer to be deposited using the chemical vapor deposition. In the shower head of the conventional chemical vapor deposition apparatus 1, the spray holes for spraying the reaction gas are not closely arranged so that it is not possible to uniformly spray the reaction gas onto the surface of the wafer. Therefore, the thin film is not uniformly deposited on the surface of the wafer to deteriorate quality of products and to cause defects in following processes. As a result, productivity deteriorates.

### DISCLOSURE OF INVENTION

### Technical Problem

Accordingly, it is an object of the present invention to provide a shower head of a chemical vapor deposition apparatus in which the spray holes formed on the surface of the shower head are divided into main holes and supplementary holes provided in the blind spots among the main spray holes so that sprayed reaction gas can be deposited onto the surface of a wafer as a thin film of uniform thickness.

### Technical Solution

In order to achieve the above object, there is provided a shower head of a chemical vapor deposition apparatus comprising a chamber having a chamber inside so that a shower head and a heater are mounted therein, a gas in port formed on one side so that a reaction gas is flown from the outside, a chamber lead combined with the top surface of the chamber by fastening means to seal up the chamber, a block plate in which the received reaction gas is distributed by through holes provided on the bottom surface of the chamber lead to form a low temperature region, a plurality of spray holes for spraying the distributed reaction gas onto the surface of a wafer, a shower head having a plurality of fastening holes formed along the outer circumference thereof to be fastened with the chamber lead, and a heater on whose top surface the wafer is settled and on whose bottom surface a heater supporter is provided, the heater being provided in the chamber inside to be separated from the shower head by a predetermined distance. A plurality of main holes are formed in the center of the top surface of the shower head to be separated from each other by the same distance. A plurality of supplementary holes are separated from the main holes by the same distance to intersect the main holes. Protrusions are formed in the center of the bottom surface of the shower head. An induction groove is provided between the protrusions to form the lower parts of the main holes and the supplementary holes. The outer circumference of the induction groove is extended toward the lower part.

### BRIEF DESCRIPTION OF THE DRAWINGS

These and/or other objects and advantages of the invention will become apparent and more readily appreciated from the following description of the preferred embodiments, taken in conjunction with the accompanying drawings of which:

FIG. 1 is a sectional view of a conventional chemical vapor deposition apparatus.

FIG. 2 is a sectional view of a chemical vapor deposition apparatus in which a shower head according to the present invention is mounted.

FIG. 3 is a sectional view of a shower head according to the present invention.

FIG. 4 is a plan view of FIG. 3.

FIG. 5 is a sectional view of a shower head according to another embodiment of the present invention.

FIG. 6 is a plan view of the shower head according to another embodiment of the present invention.

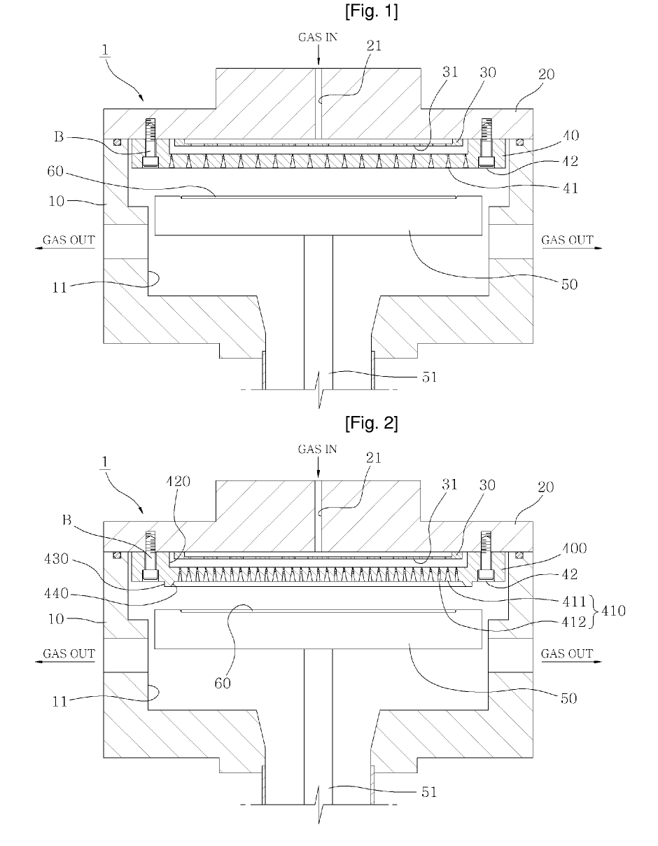

### MODE FOR THE INVENTION

Hereinafter, preferred embodiments of the present invention will be described with reference to the attached drawings.

FIG. 2 is a sectional view of a chemical vapor deposition apparatus 1 according to the present invention. In order to deposit a thin film on the surface of a wafer 60, a reaction gas is flown from a gas in port 21 of a chamber lead 20 and the received reaction gas reaches a block plate 30 that is a low temperature region formed on the bottom surface of the chamber lead 20. At this time, the reaction gas is first distributed by a plurality of through holes 31 formed in the block plate 30 and the distributed reaction gas is flown to main holes 411 and supplementary holes 412 of a shower head 400 fastened to the chamber lead 20 and having an insertion groove 420 to correspond to the block plate 30. The received reaction gas is uniformly sprayed through protrusions 430 formed in the center of the bottom surface of the shower head 400 and an induction groove 440 provided between the protrusions 430. At this time, the spray holes 410 are divided into the main holes 411 and the supplementary holes 412 so that the reaction gas is uniformly and correctly deposited on the surface of the wafer 60 to remove the blind spots that the reaction gas does not reach. The protrusions 430 are formed on the bottom surface of the shower head 400 and the induction groove 440 is formed between the protrusions 430 so that the reaction gas that flows from the spray holes 410 are not concentrated on the outer parts. In particular, the induction groove 440 extends toward the lower part so that the reaction gas can be effectively sprayed and deposited onto the surface of the wafer 60 formed on the top surface of the heater 50.

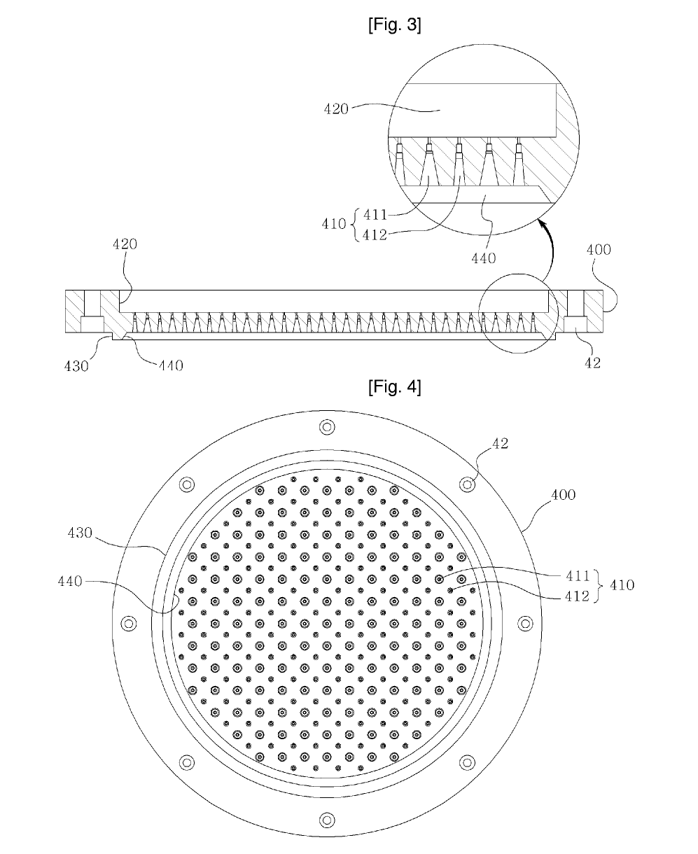

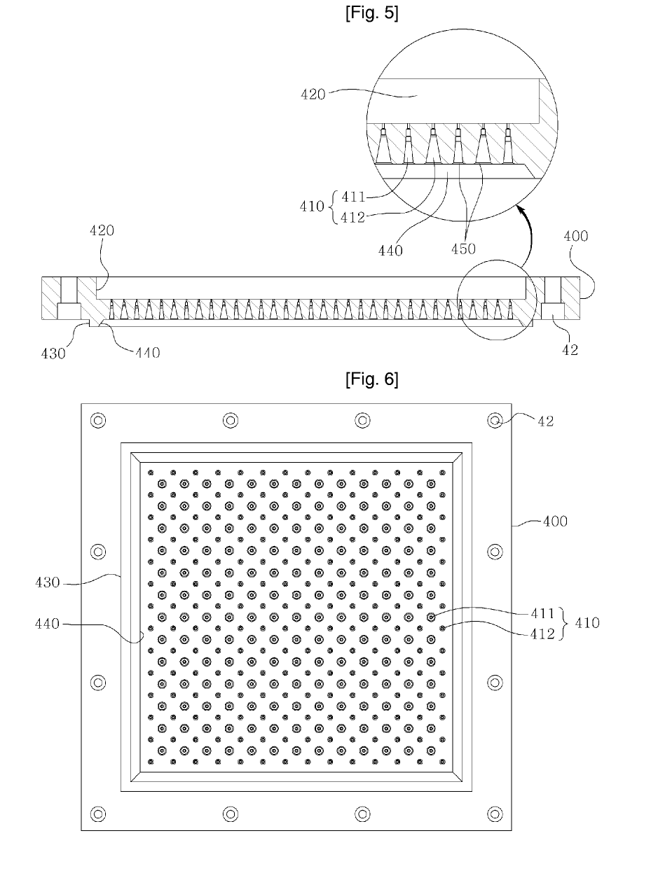

As illustrated in the sectional view of FIG. 3 and the plan view of FIG. 4, the shower head 400 includes a predetermined insertion groove 420 into which the block plate 30 is inserted from the top surface to the inside of the shower head 400, the plurality of main holes 411 formed on the surface of the insertion groove 420 to be separated from each other by the same distance, the plurality of supplementary holes 412 that are separated from the main holes 411 by the same distance and that intersect the main holes 411, and a plurality of fastening holes 42 for bolt B fastening the shower head 400 to the chamber lead 20. FIG. 5 is a sectional view of a shower head according to another embodiment of the present invention. The lower parts of the main holes 411 and the supplementary holes 412 formed from top to bottom are extended 450 so that the reaction gas is rapidly and widely sprayed. FIG. 6 is a plan view of the shower head according to another embodiment of the present invention. The shape of the shower head varies, however, the spray holes 410 and the induction groove 440 formed between the protrusions 430 are the same.

### Industrial Applicability

According to the shower head of the present invention, the main holes and the supplementary holes remove the blind spots so that it is possible to uniformly spray the reaction gas and to thus deposit the thin film of uniform thickness on the surface of the semiconductor wafer. As a result, it is possible to improve productivity.

According to the shower head of the chemical vapor deposition apparatus for depositing the reaction gas on the surface of the wafer, the supplementary holes are added in order to remove the blind spots of the spray holes and the induction groove is formed in order to prevent the reaction gas from being concentrated so that it is possible to uniformly and stably deposit the thin film on the surface of the wafer.

1. A shower head of a chemical vapor deposition apparatus comprising:
a chamber having a chamber inside so that a shower head and a heater are mounted therein;
a gas in port formed on one side so that a reaction gas is flown from the outside;
a chamber lead combined with the top surface of the chamber by fastening means to seal up the chamber;
a block plate in which the received reaction gas is distributed by through holes provided on the bottom surface of the chamber lead to form a low temperature region;
a plurality of spray holes for spraying the distributed reaction gas onto the surface of a wafer;
a shower head having a plurality of fastening holes formed along the outer circumference thereof to be fastened with the chamber lead; and
a heater on whose top surface the wafer is settled and on whose bottom surface a heater supporter is provided, the heater being provided in the chamber inside to be separated from the shower head by a predetermined distance,
wherein a plurality of main holes are formed in the center of the top surface of the shower head to be separated from each other by the same distance,
wherein a plurality of supplementary holes are separated from the main holes by the same distance to intersect the main holes,
wherein protrusions are formed in the center of the bottom surface of the shower head,
wherein an induction groove is provided between the protrusions to form the lower parts of the main holes and the supplementary holes, and
wherein the outer circumference of the induction groove is extended toward the lower part.

2. The shower head as claimed in claim 1, wherein the lower parts of the main holes and the supplementary holes formed from top to bottom are extended.
